(19) United States
(12) Patent Application Publication
(10) Pub. No.: US 2026/0212067 A1
(43) Pub. Date: Jul. 23, 2026

(54) INFORMATION PROCESSING SYSTEM, INFORMATION PROCESSING METHOD, AND PROGRAM

(71) Applicant: ispace, inc., Tokyo (JP)

(72) Inventors: Takeshi HAKAMADA, Tokyo (JP); Yoshikazu IKEDA, Tokyo (JP); Masashi SATO, Tokyo (JP); Matej PUNTER, Tokyo (JP); Katsuaki TANAKA, Tokyo (JP)

(21) Appl. No.: 19/109,450

(22) PCT Filed: Sep. 8, 2022
(86) PCT No.: PCT/JP2022/033716

§ 371 Date: Jan. 29, 2026

(51) Int. Cl. G06F 30/20; B64G 1/16; G01C 21/20

(52) U.S. Cl. CPC G06F 30/20; B64G 1/16; G01C 21/20

(57) ABSTRACT

An information processing system includes at least one processor configured to output information regarding a mission to a heavenly body other than the Earth by executing processing according to an operation of a user by using at least one of water resource data corresponding to each of points on the heavenly body other than the Earth, environmental data corresponding to each of points on the heavenly body other than the Earth, a specification and/or a given setting value of a rover, a specification and/or a given setting value of a device, an input value of the user, and a given setting value.

### TECHNICAL FIELD

The present invention relates to an information processing system, an information processing method, and a program.

### BACKGROUND ART

Conventionally, exploration of heavenly bodies (for example, the Moon and the Mars) other than the Earth has been performed, and rovers capable of traveling on heavenly bodies (for example, the Moon and the Mars) have been developed (see, for example, Patent Literature 1).

### CITATION LIST

### Patent Literature

Patent Literature 1: JP 9-272473 A

### SUMMARY OF INVENTION

### Solution to Problem

An information processing system according to a first aspect of the present invention includes at least one processor configured to output information regarding a mission to a heavenly body other than the Earth by executing processing according to an operation of a user by using at least one of water resource data corresponding to each of points on the heavenly body other than the Earth, environmental data corresponding to each of points on the heavenly body other than the Earth, a specification and/or a given setting value of a rover, a specification and/or a given setting value of a device, an input value of the user, and a given setting value.

An information processing system according to a second aspect of the present invention is the information processing system according to the first aspect, in which the output information regarding the mission is information regarding at least one of an exploration route and/or a consumed energy of the rover, an amount of water extracted by a water decomposer, an amount of power generated by a fuel cell, or an amount of generated hydrogen or oxygen.

An information processing system according to a third aspect of the present invention is the information processing system according to the first or second aspect, and further includes at least one storage device that stores water resource data including water reserves and/or a predicted water content of a regolith for each of positions on the heavenly body other than the Earth, in which the at least one processor updates water resource data corresponding to each of points on the heavenly body other than the Earth in accordance with remote sensing of a sensor provided in a satellite that orbits the heavenly body other than the Earth and/or a detection result from a sensor provided on a surface of or underground in the heavenly body other than the Earth.

An information processing system according to a fourth aspect of the present invention is the information processing system according to the third aspect, in which the at least one processor simulates a mission on the heavenly bodies other than the Earth by using the updated water resource data, and outputs information regarding a simulation result.

An information processing system according to a fifth aspect of the present invention is the information processing system according to the first aspect, in which the information regarding the mission is an acquisition cost of a water resource at a point designated by the user, and the at least one processor outputs the acquisition cost of the water resource at the point designated by the user by using environmental data corresponding to each of points on the heavenly body other than the Earth.

An information processing system according to a sixth aspect of the present invention is the information processing system according to the first aspect, in which the device is a water decomposer, the information regarding the mission is information regarding water extraction, and the at least one processor outputs the information regarding water extraction by executing processing according to an operation of the user by using a specification of the water decomposer and/or a given setting value in addition to the water resource data.

An information processing system according to a seventh aspect of the present invention is the information processing system according to the sixth aspect, in which the information regarding water extraction is an amount of water generated per unit time and/or a time required to acquire a target amount of water, the water resource data is a predicted water content of a regolith, and the at least one processor outputs the amount of water generated per unit time and/or the time required to acquire the target amount of water by using an efficiency of the water decomposer extracting water from the regolith, a regolith weight that is treatable per unit time in the water decomposer, and a predicted water content of the regolith.

An information processing system according to an eighth aspect of the present invention is the information processing system according to the first aspect, in which, in a case where a start point on the heavenly body other than the Earth and at least one target point on the heavenly body other than the Earth are input, the at least one processor outputs at least one of a first candidate route from the start point to the target point, a distance of the first candidate route, and a maximum obliquity in the first candidate route.

An information processing system according to a ninth aspect of the present invention is the information processing system according to the eighth aspect, in which the at least one processor outputs a difference in maximum obliquity and/or a difference in distance between the first candidate route and one or more second candidate routes different from the first candidate route.

An information processing system according to a tenth aspect of the present invention is the information processing system according to the ninth aspect, in which the at least one processor outputs a recommended specification of a rover corresponding to the second candidate route.

An information processing system according to an eleventh aspect of the present invention is an information processing system according to any one of the eighth to tenth aspects, and further includes at least one storage device that stores a relationship between a ratio between a horizontal traction force and a vertical load and a slip ratio for each speed of the rover, in which, in a case where a set speed of the rover is received from the user, the at least one processor obtains a ratio between a horizontal traction force and a vertical load at each movement point of the rover, determines a slip ratio corresponding to the obtained ratio in the relationship stored in the storage device, and outputs an arrival prediction time at or a required time to reach the target point by using the slip ratio.

An information processing system according to a twelfth aspect of the present invention is the information processing system according to any one of the eighth to eleventh aspects, and further includes at least one storage device that stores a relationship between a ratio between a horizontal traction force and a vertical load and a slip ratio for at least a minimum set speed of the rover, in which the at least one processor updates the relationship between the ratio between the horizontal traction force and the vertical load and the slip ratio in the storage device by using information acquired from the heavenly body other than the Earth, and outputs a maximum climbing possible inclination angle of the rover with reference to the updated relationship.

An information processing system according to a thirteenth aspect of the present invention is the information processing system according to the first aspect, in which the device is one or more fuel cells, and in a case where the user inputs a mission period in addition to a target point on the heavenly body other than the Earth, the at least one processor calculates an amount of power generated by a solar panel of the rover at the target point on the basis of the mission period, and outputs an amount of hydrogen/oxygen generated by the fuel cells in the daytime of the mission period on the heavenly body other than the Earth by using the amount of power.

An information processing system according to a fourteenth aspect of the present invention is the information processing system according to the thirteenth aspect, in which the at least one processor outputs an extension period of the mission or a total period of the mission in a case where the rover is operated in a low power mode at night of the heavenly body other than the Earth by using a reserved amount of hydrogen and a reserved amount of oxygen obtained from the amount of hydrogen/oxygen generated by the fuel cells in the daytime of the heavenly body other than the Earth.

An information processing system according to a fifteenth aspect of the present invention is an information processing system according to any one of the first to fourteenth aspects, and further includes a storage device that stores a latitude, a longitude, and an altitude on a Moon surface in association with each other, in which, in a case where the at least one processor receives the latitude, the longitude, and a search range centered on a point of the latitude and the longitude from the user, the at least one processor searches the storage device, and outputs a point where an obliquity falls within a predetermined range as a landing candidate point.

An information processing system according to a sixteenth aspect of the present invention is the information processing system according to any one of the first to fifteenth aspects, in which, in a case where a point and a time period for the heavenly body other than the Earth are received from the user, the at least one processor outputs a mission continuation period in a time period division obtained by dividing the received period.

An information processing system according to a seventeenth aspect of the present invention is the information processing system according to any one of the first to sixteenth aspects, and further includes a storage device that stores information regarding a daytime period of the heavenly body other than the Earth and/or a nighttime period of the heavenly body other than the Earth in unit time intervals, in which the at least one processor refers to the storage device to acquire, for each mission start date, a daytime or a nighttime for each unit time after the mission start date, calculates an amount of power generated from a solar panel and amounts of oxygen and hydrogen generated by a fuel cell by using the amount of generated power in the daytime, and calculates a duration for which the fuel cell will be able to generate power from oxygen and hydrogen in the fuel cell in the nighttime, thereby outputting a mission continuation period for each mission start date.

An information processing system according to an eighteenth aspect of the present invention is the information processing system according to any one of the first to seventeenth aspects, and further includes a storage device that stores information regarding a daytime period of the heavenly body other than the Earth and/or a nighttime period of the heavenly body other than the Earth in unit time intervals, in which, in a case where a latitude, a longitude, and a mission start date are received, the at least one processor refers to the storage device to acquire a daytime or a nighttime for each unit time after the mission start date for each point in a predetermined range centered on the latitude and the longitude designated by the user, calculates an amount of power generated from a solar panel and amounts of oxygen and hydrogen generated by a fuel cell by using the amount of generated power in the daytime, and calculates a duration for which the fuel cell will be able to generate power from oxygen and hydrogen in the fuel cell in the nighttime, thereby outputting a mission continuation period for each point.

An information processing system according to a nineteenth aspect of the present invention is the information processing system according to any one of the first to eighteenth aspects, and further includes a storage device that stores a latitude, a longitude, and an altitude on the heavenly body other than the Earth in association with each other, in which, in a case where a latitude and a longitude serving as a landing candidate on the heavenly body other than the Earth are received, the at least one processor refers to the storage device and calculates a landing success probability for each point in a predetermined range centered on the latitude and the longitude designated by the user according to a predetermined calculation formula, thereby outputting a landing success probability for each point.

An information processing method according to a twentieth aspect of the present invention includes a step of outputting information regarding a mission on a heavenly body other than the Earth by executing processing according to an operation of a user by using at least one of water resource data corresponding to each of points on the heavenly body other than the Earth, environmental data corresponding to each of points on the heavenly body other than the Earth, a specification and/or a given setting value of a rover, a specification and/or a given setting value of a device, an input value of the user, and a given setting value.

A program according to a twenty-first aspect of the present invention is a program for causing a computer to execute a step of outputting information regarding a mission on a heavenly body other than the Earth by executing processing according to an operation of a user by using at least one of water resource data corresponding to each of points on the heavenly body other than the Earth, environmental data corresponding to each of points on the heavenly body other than the Earth, a specification and/or a given setting value of a rover, a specification and/or a given setting value of a device, an input value of the user, and a given setting value.

### Advantageous Effects of Invention

According to one aspect of the present invention, since a user can ascertain information regarding a mission in advance, it is possible to efficiently plan a mission.

### BRIEF DESCRIPTION OF DRAWINGS

FIG. 1 is a conceptual diagram according to the present embodiment.

FIG. 2 is a conceptual diagram of a flow for achieving increase of efficiency or optimization of mission planning.

FIG. 3 is a table illustrating an example of feedback between a digital Moon surface virtual space, the Earth, and the Moon.

FIG. 4 is a schematic diagram for describing data collection.

FIG. 5 is a schematic configuration diagram of an information processing system according to the present embodiment.

FIG. 6 is a schematic configuration diagram of a terminal according to the present embodiment.

FIG. 7 is a schematic configuration diagram of a computer system according to the present embodiment.

FIG. 8 illustrates an example of screen transition related to water collection displayed on the terminal.

FIG. 9 illustrates an example of screen transition related to a search route of a rover displayed on the terminal.

FIG. 10 is a schematic diagram illustrating a dynamic model of a wheel.

FIG. 11 is a graph illustrating an example of a relationship between a ratio between a horizontal traction force and a vertical load and a slip ratio.

FIG. 12 is a schematic cross-sectional view illustrating an example of a configuration of a rover.

FIG. 13A is a schematic diagram for describing water decomposition in a fuel cell.

FIG. 13B is a schematic diagram for describing power generated by the fuel cell.

FIG. 14 illustrates an example of screen transition related to power generation in a solar panel.

FIG. 15 is a diagram illustrating an angle of sunlight, an angle of a solar panel, and an angle of an inclination.

FIG. 16 illustrates an example of a landing candidate point search screen.

FIG. 17 illustrates an example of a bar graph representing a mission continuation period for each start date and time of a mission.

FIG. 18 illustrates an example of a screen displaying the mission continuation period at each point on a Moon surface by color.

FIG. 19 illustrates an example of a screen including a graph representing a landing success probability at each point on the Moon surface by color.

### DESCRIPTION OF EMBODIMENTS

Hereinafter, each embodiment will be described with reference to the drawings. However, unnecessarily detailed description may be omitted. For example, a detailed description of well-known matters and redundant description of substantially the same configuration may be omitted. This is to avoid unnecessary redundancy of the following description and to facilitate understanding of those skilled in the art.

In a case of conducting exploration of heavenly bodies (for example, the Moon and the Mars) other than the Earth, a mission is planned in advance, but there is a problem that it takes time and effort to plan the mission, and thus it is required to increase the efficiency of planning the mission.

One aspect of the present embodiment has been made in view of the above problem, and one of the objectives thereof is to provide an information processing system, an information processing method, and a program capable of increasing the efficiently of planning a mission.

In response to this problem, the inventor of the present application has conceived a digital virtual space by reproducing situations of heavenly bodies (for example, the Moon and the Mars) other than the Earth on a computer by using various types of data collected from heavenly bodies other than the Earth by applying the conventional digital twin. The inventor of the present application has conceived to increase efficiency of or optimize mission planning by performing simulation, analysis, or optimization of exploration using a rover, water decomposition, power generation using a fuel cell, and the like in the digital virtual space. Here, the digital twin is a technology for reproducing various types of data collected from the real world on a computer.

Hereinafter, as a specific example, a heavenly body other than the Earth will be described as a Moon as an example, and a digital Moon surface virtual space will be described as an example of a digital virtual space.

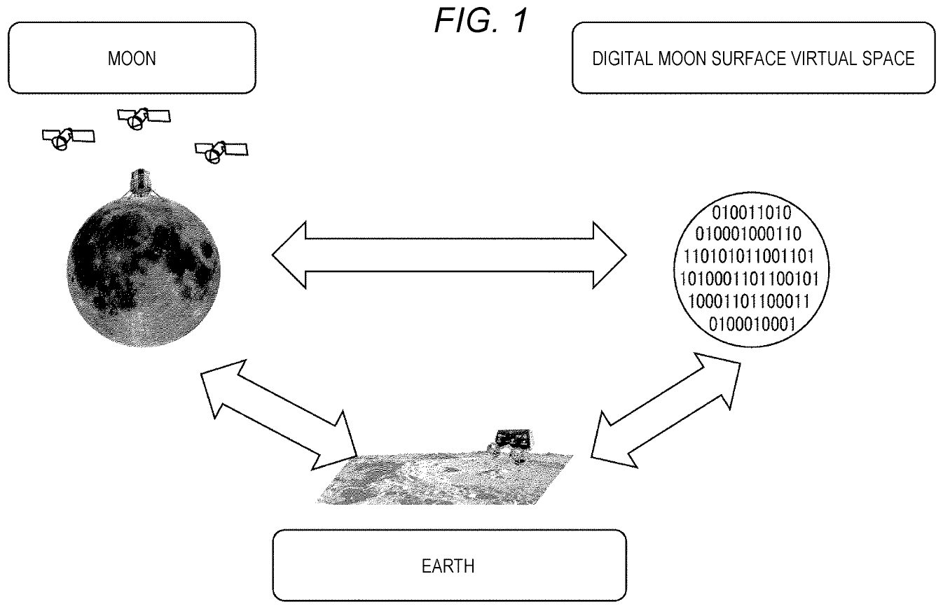

FIG. 1 is a conceptual diagram related to the present embodiment. As illustrated in FIG. 1, various types of data collected from the Moon are used to reproduce a situation of the Moon on a computer to create a digital Moon surface virtual space. In addition, data lacking in our office is supplemented by data obtained from results of experiments on the Earth.

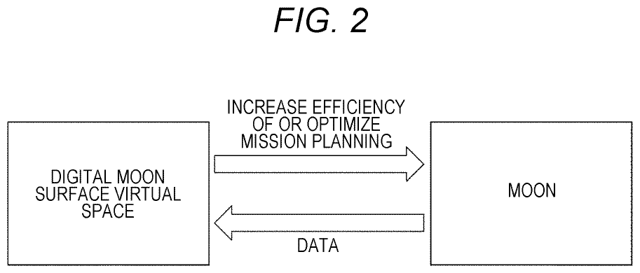

FIG. 2 is a conceptual diagram of a flow for increasing efficiency of or optimizing mission planning. Efficiency of mission planning is increased or the mission planning is optimized by performing simulation, analysis, or optimization of exploration using a rover, water decomposition, power generation using a fuel cell, and the like in a digital Moon surface virtual space on the Earth. On the other hand, data from exploration, water decomposition, and power generation and other activities in missions on the actual Moon surface is collected, and the collected data is reflected in the digital Moon surface virtual space. This can improve the accuracy of simulation, analysis, or optimization in the digital Moon surface virtual space, and can further increase efficiency of or optimize mission planning. Repeating such a cycle improves the degree of efficiency or optimization of the mission planning.

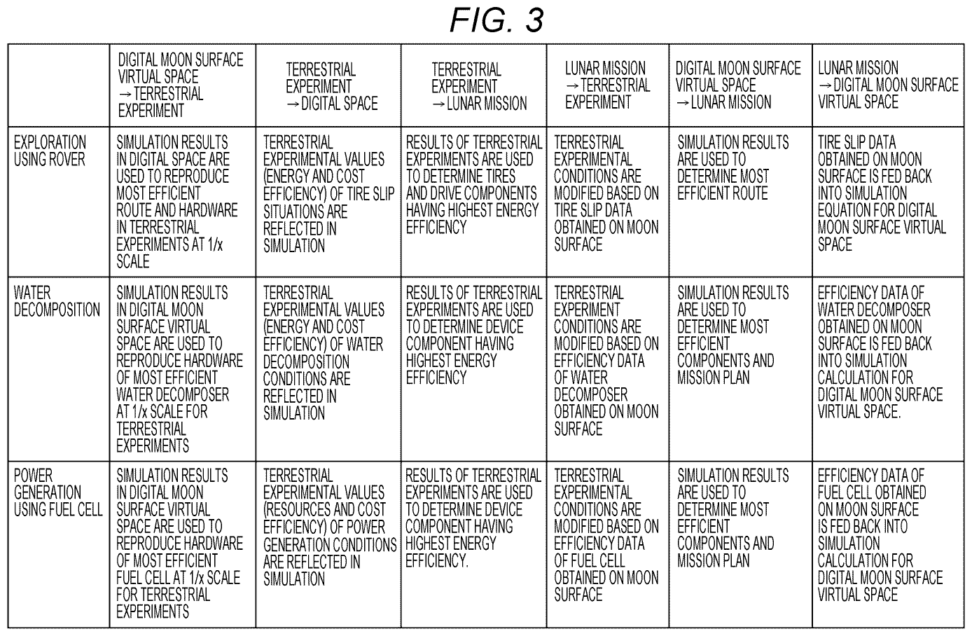

FIG. 3 is a table illustrating an example of feedback between a digital Moon surface virtual space, the Earth, and the Moon. An example of feedback will be described for each of water exploration using a rover, water decomposition, and power generation using a fuel cell. Hereinafter, the digital Moon surface virtual space will also be referred to as a digital space.

1 Water exploration using rover

(1) Feedback from digital Moon surface virtual space to terrestrial experiments

Simulation results in the digital space are used to reproduce the most efficient route and hardware of a rover in terrestrial experiments at a 1/x (where x is a natural number) scale.

(2) Feedback from terrestrial experiments to digital space

Terrestrial experimental values (energy and cost efficiency) of tire slip situations are reflected in the simulation.

(3) Feedback from terrestrial experiments to lunar mission

Results of terrestrial experiments are used to determine tires and drive components having the highest energy efficiency.

(4) Feedback from lunar missions to terrestrial experiments

Terrestrial experimental conditions are modified based on tire slip data obtained on the Moon surface.

(5) Feedback from digital Moon surface virtual space to lunar mission

Simulation results are used to determine the most efficient route.

(6) Feedback from lunar mission to digital Moon surface virtual space

Tire slip data obtained on the Moon surface is fed back into a simulation equation for the digital Moon surface virtual space.

2 Water decomposition

(1) Feedback from digital Moon surface virtual space to terrestrial experiments

Simulation results in the digital Moon surface virtual space are used to reproduce hardware of the most efficient water decomposer at the 1/x (where x is a natural number) scale for terrestrial experiments.

(2) Feedback from terrestrial experiments to digital space

Terrestrial experimental values (energy and cost efficiency) of water decomposition conditions are reflected in the simulation.

(3) Feedback from terrestrial experiments to lunar mission

Results of terrestrial experiments are used to determine a device component having the highest energy efficiency.

(4) Feedback from lunar missions to terrestrial experiments

Terrestrial experiment conditions are modified based on efficiency data of the water decomposer obtained on the Moon surface.

(5) Feedback from digital Moon surface virtual space to lunar mission

Simulation results are used to determine the most efficient components and mission plans.

(6) Feedback from lunar mission to digital Moon surface virtual space

Efficiency data of the water decomposer obtained on the Moon surface is fed back into simulation calculation for the digital Moon surface virtual space.

3 Power generation using fuel cell

(1) Feedback from digital Moon surface virtual space to terrestrial experiments

Simulation results in the digital Moon surface virtual space are used to reproduce hardware of the most efficient fuel cell at the 1/x (where x is a natural number) scale for terrestrial experiments.

(2) Feedback from terrestrial experiments to digital space

Terrestrial experimental values (resources and cost efficiency) of power generation conditions are reflected in the simulation.

(3) Feedback from terrestrial experiments to lunar mission

Results of the terrestrial experiments are used to determine a device component having the highest energy efficiency.

(4) Feedback from lunar mission to terrestrial experiments

Terrestrial experimental conditions are modified based on efficiency data of the fuel cell obtained on the Moon surface.

(5) Feedback from digital Moon surface virtual space to lunar mission

Simulation results are used to determine the most efficient components and mission plans.

(6) Feedback from lunar mission to digital Moon surface virtual space

Efficiency data of the fuel cell obtained on the Moon surface is fed back into simulation calculation for the digital Moon surface virtual space.

For example, remote sensing of a satellite orbiting a heavenly body other than the Earth and/or a detection result from a sensor provided on a surface of or underground in the heavenly body (for example, the Moon or the Mars) other than the Earth and/or infrastructure operation management data in an activity on the heavenly body (for example, the Moon or the Mars) other than the Earth are collected. Reflecting the collected data in a digital virtual space which is a virtual model reproduces an event occurring in a physical space on a heavenly body (for example, the Moon or the Mars) other than the Earth in the digital virtual space. This data collection is performed, for example, in real time.

### <Data Management of Hydrogen Value Chain>

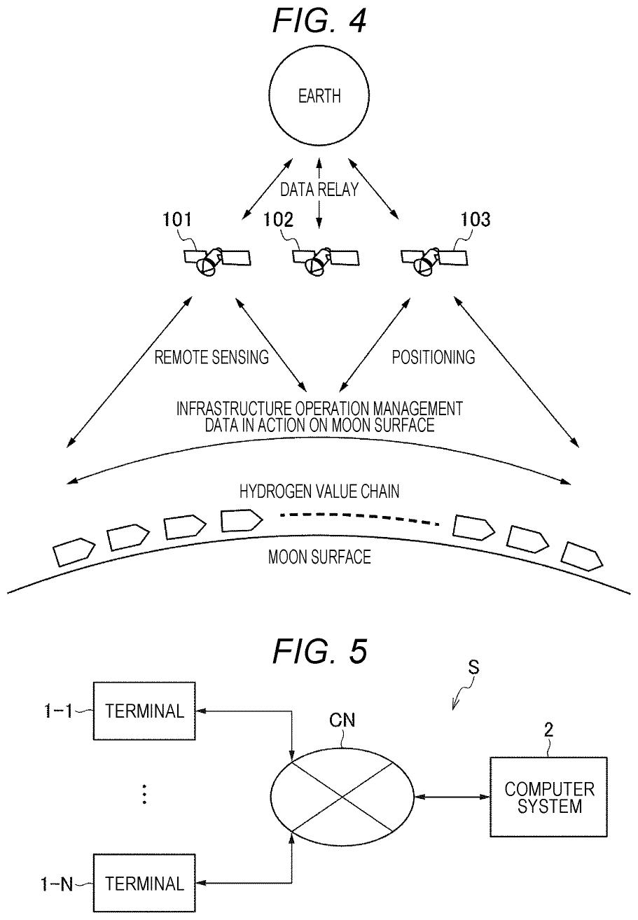

FIG. 4 is a schematic diagram for describing data collection. First, management of a hydrogen value chain on the Moon surface will be described with reference to FIG. 4. Infrastructure operation management data (for example, hydrogen value chain management data) in an activity on the Moon surface is collected, for example, in real time, transferred to the Earth via satellites 101, 102, and 103 orbiting the Moon, and accumulated as data in the digital Moon surface virtual space.

Here, the hydrogen value chain management data includes, for example, a hydrogen accumulation amount at each position on the Moon surface. Specifically, for example, a tank that stores hydrogen (hereinafter, also referred to as a hydrogen tank) may be provided with a sensor device. In this case, the sensor device, the sensor device may include, for example, a sensor that detects an amount of stored hydrogen, a GPS receiver, and a wireless communication module that communicates with the satellites 101, 102, and 103. In a case where the hydrogen tank stores liquid hydrogen, the sensor may be a water level gauge that measures a water level of the liquid.

The satellites 101, 102, and 103 are, for example, global positioning system (GPS) satellites. Signals from the satellites 101, 102, and 103 include time data from atomic clocks mounted on the satellites, information regarding the almanac (orbit) of the satellites, and the like. The sensor device receives radio waves from the satellites 101, 102, and 103, measures the transmission time, and multiplies the time difference between the transmission and the reception by the propagation velocity (speed of light) of the radio waves to determine the distance from the satellite. The GPS receiver receives radio waves from three or more satellites 101, 102, and 103, and simultaneously obtains accurate reception time and receiver coordinates (points in a three-dimensional space) through positioning calculation.

Specifically, for example, the principle of GPS positioning is based on the fact that the light speed c is constant in a local inertial system.

If both the GPS satellite and the GPS receiver have a clock that can be regarded as accurate, a distance can be obtained by multiplying a difference between a transmission time (measurement value) T and a reception time t by the light speed c. Assuming that a position of a GPS satellite is represented by coordinates (Xi, Yi, Zi) and a position of a GPS receiver is represented by (x, y, z), the following relational expression is established.

$${{c}^{2} ( {T}_{i} - t )}^{2} = {( {X}_{i} - x )}^{2} + {( {Y}_{i} - y )}^{2} + {( {Z}_{i} - z )}^{2} \qquad [ Math . 1 ]$$

To obtain the position of the GPS satellite, a navigation message signal superimposed on the received data is demodulated and combined with the transmission time. The reception time t is a value of the clock of the GPS receiver. Here, as an example, it is assumed that the clock of the GPS receiver is accurate. The three variables (unknowns) x, y, and z representing the position of the GPS receiver are obtained by solving three simultaneous equations in which the coordinates of three different GPS satellites (here, the satellites 101, 102, and 103) are substituted.

As a result, a position on the Moon surface is obtained. The wireless communication module transmits a set of the obtained position of the GPS receiver (that is, the position of the hydrogen tank) and the detected hydrogen amount to the satellites 101, 102, and 103, and the set is transferred to the Earth by the satellites 101, 102, and 103 and is accumulated as data of the digital Moon surface virtual space. As a result, the hydrogen accumulation amount at each position on the Moon surface can be managed on the Earth without delay, for example.

Note that, in a case where the clock of the GPS receiver is not so accurate, the reception time t also needs to be an unknown value, and thus these four unknowns are obtained by receiving from four or more satellites.

### <Management of Water Resource Data>

Next, management of data of water resources reserved in the Moon will be described with reference to FIG. 4. An amount of water resources reserved on the Moon is estimated through remote sensing using sensors provided in the satellites 101 to 103 that orbits the Moon. Here, for example, the satellites 101 to 103 may be provided with, for example, a processor, an irradiation mechanism (for example, synthetic aperture radar (SAR)) that applies electromagnetic waves, and a sensor, and the sensor mounted on the satellites 101 to 103 may estimate an amount of water resources by observing reflected electromagnetic waves by utilizing the fact that the electromagnetic waves applied from the irradiation mechanism are reflected by the Moon surface. In a case where the irradiation mechanism is SAR, microwave or millimeter wave irradiation may be performed. Alternatively, the irradiation mechanism may apply terahertz waves.

Here, an example in which the irradiation mechanism is provided in the satellites 101 to 103 has been described, but the present invention is not limited thereto, and the satellites 101 to 103 may be provided with, for example, a visible light camera or an infrared camera. In this case, a visible light camera or an infrared camera may capture an image of the Moon surface, and an amount of water resources may be estimated from the captured image.

Here, the estimation of the amount of water resources may be performed by the processor of the satellites 101 to 103 or may be performed by a processor 26 of a computer system 2 on the Earth.

Hereinafter, a case where the amount of water resources is estimated by the processor of the satellites 101 to 103 will be described. In this case, a set of reflected positions on the Moon surface and the amount of water resources is transferred to the Earth by the satellites 101, 102, 103 and accumulated as part of data of the digital Moon surface virtual space in a storage device on the Earth (for example, a storage device 23 of the computer system 2). As a result, water resource data at each position on the Moon surface can be managed on the Earth without delay, for example.

Additionally or alternatively, an amount of water resources may be sensed by a sensor device provided on the surface of or underground in the Moon, in which case the sensor device may have a sensor that senses an amount of water resources, a wireless communication module that wirelessly communicates with the satellites 101 to 103, and a GPS receiver. As a result, the amount of water resources detected by the sensor and the position obtained by the GPS receiver may be transmitted to the satellites 101 to 103 by the wireless communication module.

In this case, a set of the amount of water resources detected by the sensor and a position obtained by the GPS receiver is transferred to the Earth via the satellites 101, 102, and 103, and is accumulated as part of data of the digital Moon surface virtual space in a storage device (for example, the storage device 23 of the computer system 2) on the Earth. As a result, water resource data at each position on the Moon surface can be managed on the Earth without delay, for example.

FIG. 5 is a schematic configuration diagram of an information processing system according to the present embodiment. As illustrated in FIG. 5, an information processing system S includes terminals 1-1, . . . , 1-N (where N is a natural number) and a computer system 2. Each of the terminals 1-1, . . . , 1-N is communicatively connected to the computer system 2 via the communication circuit network CN. Here, the terminals 1-1, . . . , 1-N are, for example, computers such as smartphones, tablet terminals, notebook computers, or personal computers. Hereinafter, the terminals 1-1, . . . , 1-N are also collectively referred to as a terminal 1.

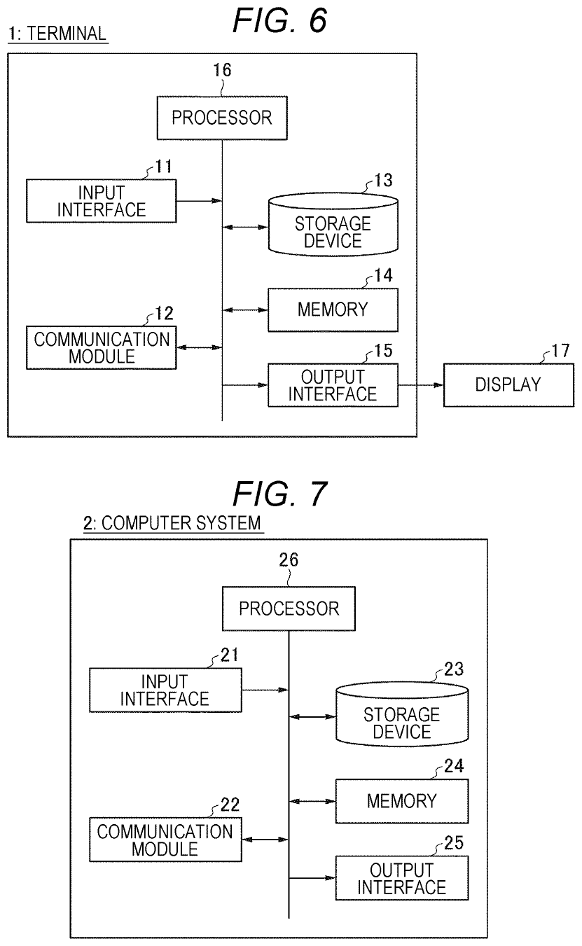

FIG. 6 is a schematic configuration diagram of the terminal according to the present embodiment. As illustrated in FIG. 6, the terminal 1 includes, for example, an input interface 11, a communication module 12, a storage device 13, a memory 14, an output interface 15, and a processor 16. Note that, here, as one aspect, the terminal 1 will be described as including one processor 16, but may include a plurality of processors, that is, one or more processors. Furthermore, here, as one aspect, a description will be made assuming that the terminal 1 includes one storage device 13, but may include a plurality of storage devices, that is, one or more storage devices.

The input interface 11 receives an input from a user and outputs an input signal corresponding to the received input to the processor 16. The communication module 12 is connected to the communication circuit network CN and communicates with the computer system 2. This communication may be wired or wireless.

The storage device 13 is, for example, a storage, and stores a program to be read and executed by the processor 16. The memory 14 temporarily stores data and programs. The memory 14 is a volatile memory and is, for example, a random access memory (RAM). The output interface 15 can be connected to, for example, the display 17, and can output, for example, a video signal to the display 17. The processor 16 loads a program from the storage device 13 into the memory 14 and executes a series of instructions included in the program to execute various processes. Note that the display 17 will be described as being externally attached to the terminal 1, but may be built in the terminal 1.

FIG. 7 is a schematic configuration diagram of the computer system according to the present embodiment. As illustrated in FIG. 7, the computer system 2 includes an input interface 21, a communication module 22, a storage device 23, a memory 24, an output interface 25, and a processor 26. Note that, here, as one aspect, the computer system 2 will be described as including one processor 26, but may include a plurality of processors, that is, one or more processors. Furthermore, here, as one aspect, the computer system 2 will be described as including one storage device 23, but may include a plurality of storage devices, that is, one or more storage devices.

The input interface 21 receives an input from an administrator (for example, an employee of a management organization) of the computer system 2 and outputs an input signal corresponding to the received input to the processor 26.

The communication module 22 is connected to the communication circuit network CN and communicates with each of the terminals 1-1, . . . , 1-N. This communication may be wired or wireless.

The storage device 23 stores programs and various types of data to be read and executed by the processor 26. The memory 24 temporarily stores data and programs. The memory 24 is a volatile memory, and is, for example, a random access memory (RAM). The output interface 25 can be connected to an external device and can output a signal to the external device. The processor 26 loads a program from the storage device 23 into the memory 24 and executes a series of instructions included in the program to execute various processes.

### <Outline of Processing of Processor 26>

An outline of processing of the processor 26 will be described. In one aspect, the processor 26 uses at least one of water resource data corresponding to each of points on a heavenly body (for example, the Moon) other than the Earth, environmental data corresponding to each of points on the heavenly body other than the Earth, a specification and/or a given setting value of a rover, a specification (for example, a water decomposer or a fuel cell) and/or a given setting value of a device, an input value of a user, and a given setting value, to execute processing according to an operation of a user, thereby outputting information regarding a mission on the heavenly body other than the Earth.

The output information regarding the mission here may be the acquisition cost of a water resource at a point designated by the user. In this case, the processor 26 may output the acquisition cost of the water resource at the point designated by the user by using environment data (for example, a terrain) corresponding to each of points on the heavenly body other than the Earth. For example, the longer the distance from the start point to the target point, the larger the acquisition cost of the water resource may be. Additionally or alternatively, for example, the acquisition cost of the water resource may be increased as a gradient of a terrain from the start point to the target point becomes steeper.

In one aspect, the storage device 23 stores water resource data including water reserves and/or a predicted water content of a regolith for each of positions on a heavenly body other than the Earth. In this case, the processor 26 updates the water resource data corresponding to each of points on the heavenly body (for example, the Moon) other than the Earth through remote sensing using a sensor provided in the satellite orbiting the heavenly body (for example, the Moon) other than the Earth and/or a detection result from a sensor provided on the surface of or under the heavenly body other than the Earth.

In one aspect, the processor 26 simulates a mission on the heavenly body (for example, the Moon) other than the Earth by using the updated water resource data, and outputs information regarding a simulation result.

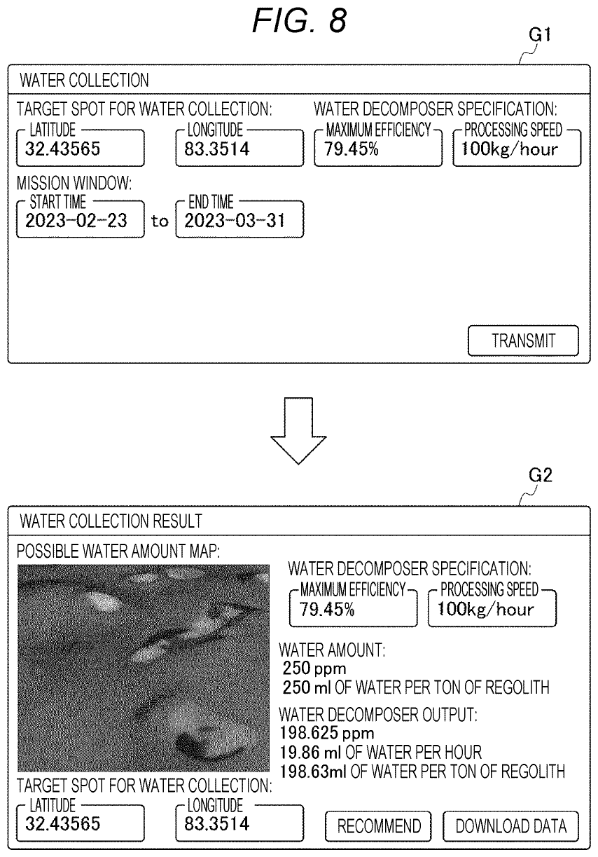

FIG. 8 is an example of screen transition related to water collection displayed on the terminal. As illustrated in FIG. 8, a latitude and a longitude of a target spot for water collection on the Moon surface, a start time (for example, the start date) of a mission, an end time (for example, the end date) thereof, the maximum efficiency of the water decomposer, and a processing speed can be input by a user on a screen G1. As a result, a user who uses the terminal 1 can perform setting by inputting these parameters.

As illustrated in FIG. 8, when a “transmit” button is pressed on the screen G1, the screen G1 transitions to a screen G2. In the screen G2, a three-dimensional map in the vicinity of the latitude and the longitude of the target point and a region in which water is reserved in the three-dimensional map are visualized. Here, as an example of visualization, for example, a region where water is reserved in the three-dimensional map is colored (for example, colored with light blue).

In addition, as illustrated in the screen G2, a preset reserve ratio of water is displayed as a numerical value (for example, 250 ppm). Further, as illustrated in the screen G2, an output (for example, 198.625 ppm) of the water decomposer is displayed. The output from the water decomposer is a product of the preset reserve ratio of water and the maximum efficiency of the water decomposer, and is calculated by the processor 26.

### <Specific Example of Output Method of Water Reserve Point>

Processing of the computer system 2 until the screen G2 is output will be described. The storage device 23 stores water resource data. Specifically, for example, a record of a set of a reserve of water and a position of the Moon surface (for example, a latitude and a longitude) is accumulated in the storage device 23. The processor 26 of the computer system 2 may refer to the storage device 23, acquire a reserve of water at each point in a predetermined range based on a latitude and a longitude of a target point input by the user, and output information obtained by visualizing a region where water is reserved in the three-dimensional map.

<Method for Outputting Amount of Water Generated Per Unit Time and/or Time Required to Acquire Target Amount of Water>

An amount of water generated per unit time is calculated by multiplying the efficiency (for example, 79.45%) of the water decomposer extracting water from a regolith by a weight (for example, 100 kg/h) of the regolith that can be treated per unit time of the water decomposer and a predicted water content (for example, 250 ppm) of the regolith. In a case where a target amount of water is set or input by the user, the time required to acquire the target amount of water is obtained by dividing the target amount of water by an amount of water generated per unit time.

As described above, the processor 26 may output information regarding water extraction by executing processing according to an operation of the user by using the specification and/or a given setting value of the water decomposer in addition to the water resource data.

Here, for example, the information regarding the mission may be an amount of water generated per unit time and/or the time required to acquire a target amount of water. In this case, the processor 26 may output the amount of water generated per unit time and/or the time required to acquire the target amount of water by using the efficiency of the water decomposer extracting water from the regolith, the weight of the regolith that can be treated per unit time of the water decomposer, and the predicted water content of the regolith included in the water resource data.

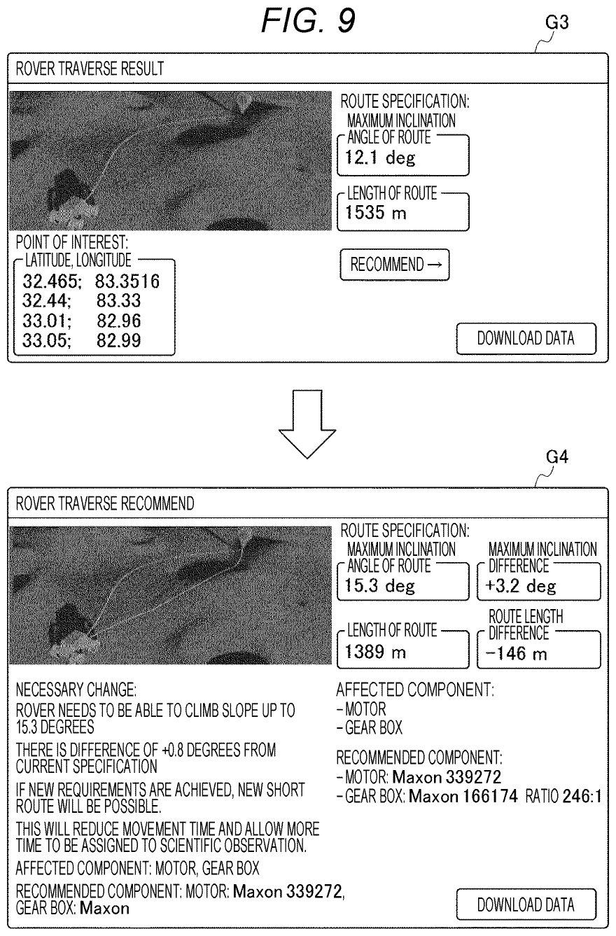

FIG. 9 illustrates an example of screen transition related to an exploration route of a rover displayed on the terminal. As illustrated in FIG. 9, the user can designate a start point and a target point of the rover on a three-dimensional map on a screen G3. Furthermore, latitudes and longitudes of one or more points of interest (that is, relay points) desired by the user can be input. When these are input by the user, as an example, a line of a first candidate route passing through the point of interest is displayed on the three-dimensional map, and the maximum inclination angle and a route length in the first candidate route are displayed as a route specification. For example, when a “recommend” button is pressed on the screen G3, the screen G3 transitions to a screen G4.

For example, in addition to the line of the route displayed on the three-dimensional map, a second candidate route is displayed by, for example, a line of another color on the screen G4. For example, the maximum inclination angle and a route length of the second candidate route are displayed on the screen G4. In addition, on the screen G4, for example, a difference in the maximum inclination angle of the second candidate route with respect to the first candidate route and a difference in the route length of the second candidate route with respect to the first candidate route are displayed.

Further, for example, necessary change information is displayed on the screen G4. The necessary change information is, for example, the following information. “The rover needs to be able to climb up to 15.3 degrees. There is a difference of +0.8 degrees from the current specification. If new requirements are established, a new short route will be possible. This will reduce movement time and allow more time for scientific observation.”

Furthermore, for example, the type of component (for example, a motor or a gear box) that affects movement along the second candidate route is displayed on the screen G4. In addition, for example, a recommended component for movement along the second candidate route is displayed for each type of component (for example, a motor or a gear box) on the screen G4.

### <Specific Example of Processing Method>

An example of processing for displaying the first candidate route of the screen G3 is as follows. For example, an altitude at each point on the Moon surface is stored in the storage device 23 of the computer system 2.

When a latitude and a longitude of the start point of the rover, the target point, and one or more relay points desired by the user are input by the user, the processor 26 of the computer system 2 searches for a route from the start point of the rover to reach the target point through all of the one or more relay points desired by the user within a range of maximum obliquity at which the rover can be ascended according to a preset default rover specification. As a result of the search, the processor 26 outputs information for displaying the first candidate route that satisfies conditions to the terminal 1. Consequently, the terminal 1 receives this information, and the processor 16 of the terminal 1 performs control to display the first candidate route by using the information. As a result, the first candidate route of the screen G3 is displayed on the terminal 1.

An example of processing for displaying the second candidate route of the screen G4 and a recommended component of the rover in the case of the second candidate route is as follows. For example, the altitude at each point on the Moon surface is stored in the storage device 23 of the computer system 2. In addition, the storage device 23 stores, for example, a specification of a combination of components and the maximum obliquity at which the rover can be ascended according to the combination of components in association with each other.

For example, the processor 26 of the computer system 2 searches for the shortest route among the routes from the start point of the rover to the target point in the range of the maximum obliquity at which the rover can be ascended by the specification of the combination of components recorded in the storage device 23. As a result of the search, the processor 26 outputs, to the terminal 1, information for displaying information (for example, a model number and a specification) that specifies the second candidate route satisfying conditions and a combination of components that can ascend the second candidate route. As a result, the terminal 1 receives this information, and the processor 16 of the terminal 1 performs control to display the second candidate route and information (for example, a model number and a specification) specifying a combination of components that can ascend the second candidate route by using the information. As a result, the screen G4 is displayed on the terminal 1.

As described above, in a case where a start point of a heavenly body (here, the Moon as an example) other than the Earth and at least one target point of the heavenly body (here, the Moon as an example) other than the Earth are input, the processor 26 may output at least one of the first candidate route from the start point to the target point, a distance of the first candidate route, and the maximum obliquity in the first candidate route.

The processor 26 may also output a difference in maximum obliquity and/or a difference in distance between the first candidate route and one or more second candidate routes different from the first candidate route. In addition, the processor 26 may output a recommended specification of a rover corresponding to the second candidate route.

### <Slip Ratio>

A regolith exists on the Moon surface, wheels of the rover slip, and thus an arrival prediction time at or a required time to reach a target point varies. Therefore, it is necessary to predict a slip ratio in advance.

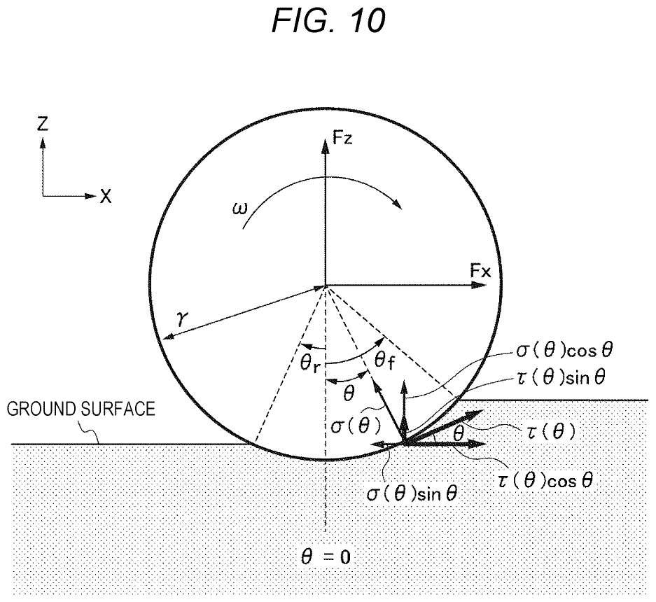

FIG. 10 is a schematic diagram illustrating a dynamic model of a wheel. Assuming that r is a wheel radius, b is a wheel width, σ is a vertical stress, τ is a shearing stress, ω is a wheel angular velocity, W is a vertical load, DP is a net traction force, and θ is a rotation angle of the wheel, a driving torque T and a horizontal traction force Fₓ and a vertical load F_{z} are expressed by the following equation, where θ_{f} is an angle at which the wheel starts to contact with the ground, and θᵣ is an angle at which the wheel leaves the ground.

$$T = {r}^{2} b {\int }_{{θ}_{r}}^{{θ}_{f}} τ ( θ ) d ( θ ) \qquad [ Math . 2 ]$$

$${F}_{z} = W = rb {\int }_{{θ}_{r}}^{{θ}_{f}} \{ σ ( θ ) cos θ + τ ( θ ) sin θ \} d θ$$

$${F}_{x} = DP = rb {\int }_{{θ}_{r}}^{{θ}_{f}} \{ τ ( θ ) cos θ - σ ( θ ) sin θ \} d θ$$

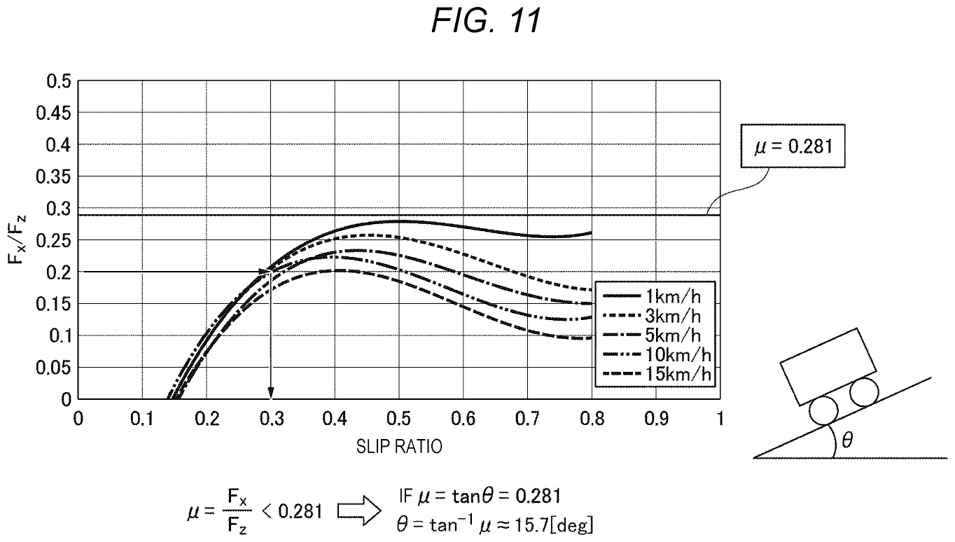

FIG. 11 is a graph illustrating an example of a relationship between a ratio between the horizontal traction force and the vertical load and a slip ratio. As illustrated in FIG. 11, a relationship between a ratio u (=Fₓ/F_{z}) between the horizontal traction force and the vertical load and the slip ratio is different for each speed of the rover. In the example in FIG. 11, the ratio μ between the horizontal traction force and the vertical load takes the maximum value when the speed of the rover is 1 km/h, and a value at that time is 0.281. In this case, since the inclination angle θ is calculated by tan⁻¹μ and is about 15.7 degrees, the maximum climbing possible angle is 15.7 degrees. As illustrated in FIG. 11, the lower the speed of the rover, the larger the maximum climbing possible angle at the speed. The relationship between the ratio μ (=Fₓ/F_{z}) between the horizontal traction force and the vertical load and the slip ratio is obtained through an experiment of the rover on the sand on the Earth for each speed of the rover and is set in advance.

On the actual Moon surface, the regolith on the Moon surface is different from the sand on the Earth, and the environment such as gravity is also different. For this reason, the relationship between the ratio μ (=Fₓ/F_{z}) between the horizontal traction force and the vertical load and the slip ratio determined in advance is not satisfied on the Moon surface. When the ratio μ (=Fₓ/F_{z}) between the horizontal traction force and the vertical load is given on the Moon surface, the slip ratio is obtained by measuring an actual movement distance of the rover. Since a speed of the rover at that time is obtained by dividing the movement distance by the time taken for the movement, the processor 26 may update the relationship between the ratio μ (=Fₓ/F_{z}) between the horizontal traction force and the vertical load and the slip ratio at the speed of the rover.

In response to this update, the processor 26 may also update the maximum climbing possible angle. That is, the storage device 23 may store the relationship between the ratio between the horizontal traction force and the vertical load and the slip ratio for the minimum set speed of the rover (for example, 1 km/h). In this case, the processor 26 may update the relationship between the ratio between the horizontal traction force and the vertical load and the slip ratio in the storage device 23 by using information acquired from a heavenly body (for example, the Moon) other than the Earth, and output the maximum climbing possible inclination angle of the rover with reference to the updated relationship.

For example, in a case where the speed of the rover is 10 km/h, when the ratio μ (=Fₓ/F_{z}) of the horizontal traction force and the vertical load is 0.2 in the example of FIG. 11, the slip ratio is obtained as 0.3 from the graph of FIG. 11. As described above, when the relationship between the ratio between the horizontal traction force and the vertical load and the slip ratio is set for each speed of the rover, the slip ratio is obtained on the basis of the speed of the rover and the ratio μ (=Fₓ/F_{z}) between the horizontal traction force and the vertical load.

### <Processing of Estimating Slip Ratio and Estimating Arrival Prediction Time at or Required Time to Target Point>

Next, an example of processing of estimating a slip ratio and estimating an arrival prediction time at or a required time to reach a target point by using the estimated slip ratio will be described. The storage device 23 may store, for example, a relationship between the ratio between the horizontal traction force and the vertical load and the slip ratio for each speed of the rover. In this case, when receiving the set speed of the rover from the user, the processor 26 may obtain the ratio μ (=Fₓ/F_{z}) between the horizontal traction force and the vertical load at each movement point of the rover, determine a slip ratio corresponding to the obtained ratio μ (=Fₓ/F_{z}) in the relationship stored in the storage device 23, and output an arrival prediction time at or a required time to reach the target point by using the slip ratio. Here, a movement distance can be obtained by a product of the movement speed of the rover, the slip ratio, and the movement time of the rover. Since a distance to the target point is known, the required time to reach the target point can be estimated by dividing the distance to the target point by the product of the movement speed of the rover and the slip ratio. Furthermore, by adding this required time to a time at that time point, an arrival prediction time at the target point can be estimated.

### <Fuel Cell>

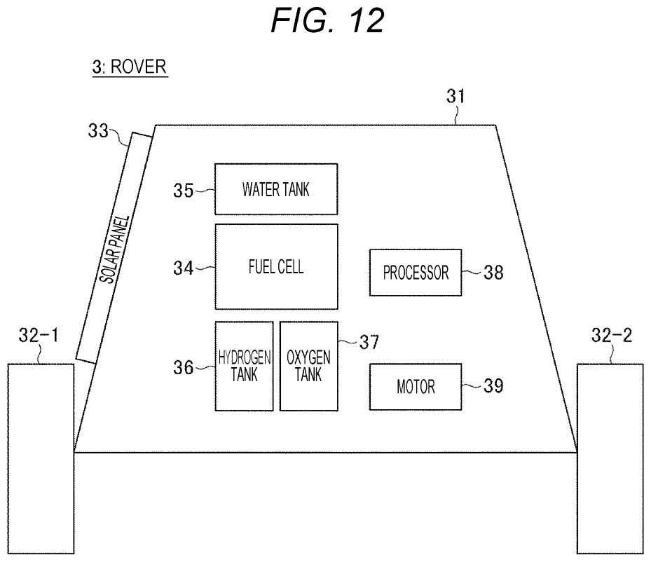

FIG. 12 is a schematic cross-sectional view illustrating an example of a configuration of a rover 3. As illustrated in FIG. 12, the rover 3 includes a housing 31, wheels 32-1 and 32-2, and a solar panel 33 provided on a surface (here, a side surface as an example) of the housing 31. The rover 3 further includes at least one fuel cell 34, a water tank 35, a hydrogen tank 36, an oxygen tank 37, a processor 38, and a motor 39 that drives the wheels 32-1 and 32-2, which are stored in the housing 31. The processor 38 controls at least the fuel cell 34 and the motor 39.

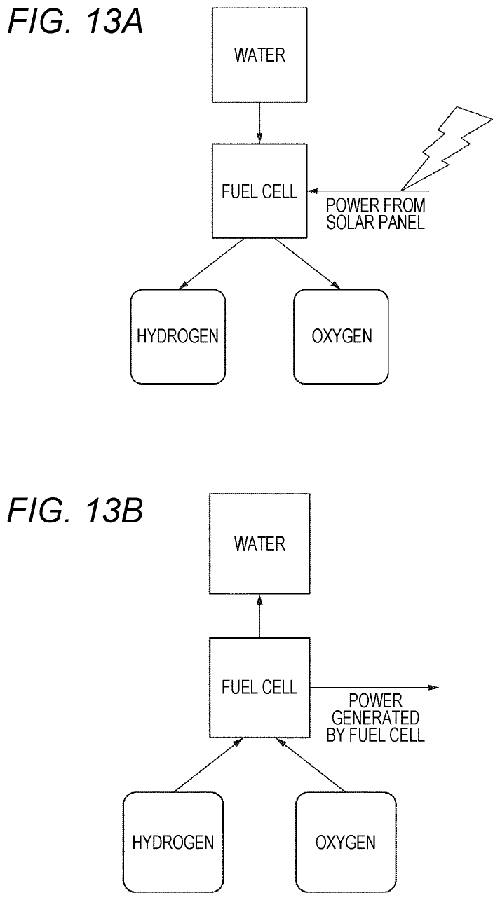

Subsequently, water decomposition using the fuel cell and power generated by the fuel cell on the Moon surface will be described with reference to FIGS. 13A and 13B. FIG. 13A is a schematic diagram illustrating water decomposition by a fuel cell. As illustrated in FIG. 13A, for example, power generated by the solar panel 33 on the Moon surface is supplied to the fuel cell 34, and the fuel cell 34 uses the power to decompose water into hydrogen and oxygen, stores the hydrogen in the hydrogen tank 36, and stores the oxygen in the oxygen tank 37. For example, hydrogen may be stored in the hydrogen tank 36 under pressure, and oxygen may be stored in the oxygen tank 37 under pressure. In this case, hydrogen and oxygen may be in a gaseous state or a liquid state. As described above, for example, water decomposition is executed by the power generated by the solar panel mounted on the rover, and hydrogen and oxygen are stored.

FIG. 13B is a schematic diagram illustrating power generated by the fuel cell. As illustrated in FIG. 13B, the fuel cell 34 generates water and power from hydrogen and oxygen. The generated power is supplied to the processor 38 and the motor 39.

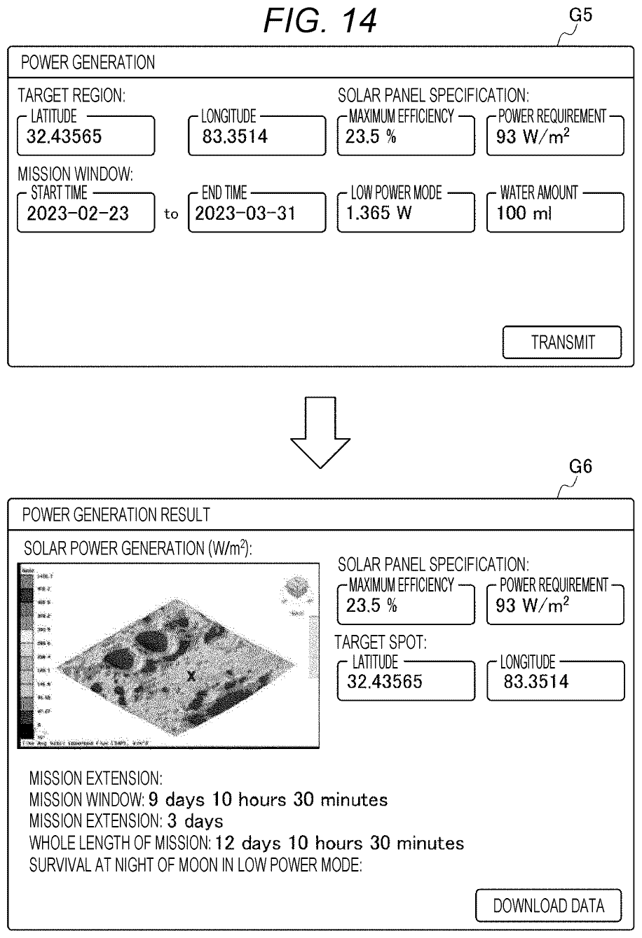

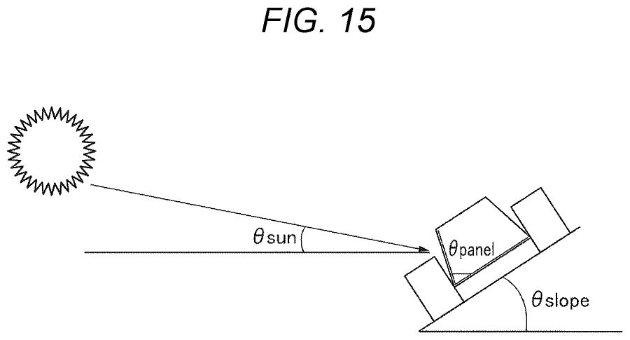

FIG. 14 illustrates an example of screen transition related to power generation using the solar panel. As illustrated in a screen G5 of the terminal 1 in FIG. 14, a latitude and a longitude of a target region of the Moon surface, a start time and an end time of a mission possible period, the maximum efficiency and power requirements (for example, the minimum required amount of power generated per square meter) as a power generation specification of the solar panel, the power consumption when the rover is in a low power mode, and a water volume of a water tank (for example, the water tank 35 of the rover 3) are displayed to be able to be input. As described above, the user of the terminal 1 can set the above parameters. When a “transmit” button is pressed on the screen G5 of the terminal 1 in FIG. 14, the screen G5 transitions to a screen G6.

As illustrated in a screen G6 of the terminal 1 in FIG. 14, an amount of power generated per unit area by the solar panel at each point (for example, an amount of power generated per square meter) is displayed by color on the map around the target region on the Moon surface. In addition, a point where an amount of power generated per square meter is selected by the processor 26 from the minimum required amount of power generated per square meter input on the screen G5 is displayed by, for example, a cross mark. In order to realize this processing, the storage device 23 may store an amount of power generated per unit area and the altitude at each point on the Moon surface. The processor 26 may refer to the storage device 23 and select a point that is as flat as possible and has no obstacle around the point among points that satisfy the minimum required amount of power generated per square meter input on the screen G5.

Further, as an example, the maximum efficiency and power requirements (for example, the minimum required amount of power generated per square meter) as a power generation specification of the solar panel, and a latitude and a longitude of the target region of the Moon surface, which are input on the screen G5, are displayed.

The screen G6 of the terminal 1 displays a mission extension period that can be extended by using power generation in the fuel cell at night of the Moon and a low power mode at night of the Moon. Here, the low power mode is a mode in which less power is consumed than in a normal power mode, and is, for example, power necessary for maintaining the temperature of an electronic device of the rover at night on the Moon surface at a durable minimum temperature (for example, −40° C.).

For example, while the power generation in the fuel cell at night and the normal power mode at night have, for example, a mission period of 9 days, 10 hours, and 30 minutes, it is illustrated that the mission period can be extended by 3 days by using the power generation in the fuel cell at night and the low power mode at night.

### <Method of Calculating Mission Extension Period>

On the Moon surface, for example, day and night are switched every 14 days. Since power cannot be generated by the solar panel at night, the supply of power is maintained through power generation using the fuel cell. Here, the power consumption per unit time in the normal mode is set in advance, and the power consumption per unit time in the low power mode is input by the user on the screen G5.

During daytime on the Moon surface, the water stored in the water tank 35 is electrolyzed by using the power generated by the solar panel 33 to store hydrogen and oxygen. During the night on the Moon, the solar panel cannot generate power with sunlight. On the other hand, since the temperature of the night on the Moon surface is extremely low, a failure or an abnormality may occur when the temperature of the electronic device of the rover becomes extremely low. Therefore, it is required to maintain the temperature of the electronic device of the rover at, for example, the durable minimum temperature (for example, −40° C.) or more, but how to procure the power during that period becomes a problem. Therefore, during the night on the Moon surface, power generated when water is synthesized from the stored hydrogen and oxygen is used. Hereinafter, processing in a case where a mission period is designated by a user will be described in the order of (1) calculation of an amount of power generated by the solar panel, (2) calculation of amounts of generated hydrogen and oxygen, and (3) an operable period in a low power mode using the fuel cell as a power source.

### (1) Calculation of Amount of Power Generated by Solar Panel

First, an amount of power generated by the solar panel with light from the sun will be described. FIG. 15 is a diagram illustrating an angle of sunlight, an angle of the solar panel, and an angle of an inclination. As illustrated in FIG. 15, θₛᵤₙ is an angle of the sun with respect to the Moon surface, θₛₗₒₚₑ is an angle of a slope on which the rover is located, and θₚₐₙₑₗ is an erection angle of the solar panel. Here, energy per unit area of the sunlight is Qₛᵤₙ, an area of the solar panel is A, a reduction coefficient of the output due to the angle θₛᵤₙ of the sun is Fₛᵤₙ, a reduction coefficient of the power due to the angle θₚₐₙₑₗ of the solar panel is Fₚₐₙₑₗ, a reduction coefficient of the power due to the angle θₛₗₒₚₑ of the slope is Fₛₗₒₚₑ, and a coefficient (energy absorption ratio) due to the surface finish of the solar panel is α. The energy Q received by the solar panel is expressed by the following equation.

$$Q = {Q}_{sun} \times A \times {F}_{sun} \times {F}_{panel} \times {F}_{slope} \times α$$

In addition, when the conversion efficiency from solar power generation to electricity of the panel is β, an amount of generated power Q_{electric} of the solar panel is expressed by the following equation.

$${Q}_{electric} = Q \times β$$

### (2) Amounts of Generated Hydrogen and Oxygen

For example, the following description will be given assuming that the initial 10 days of the mission period are daytime. Hereinafter, when the amount of generated power Q_{electric} of the solar panel is 197 W, specific examples of amounts of hydrogen and oxygen generated from the fuel cell in 10 days will be described.

Assuming that an input voltage and an input current of the fuel cell are 1.8 V and 0.7 A, respectively, an amount of power required to perform water decomposition in the fuel cell is 2.1 (=1.8×0.7) W. When 197 W, which is the amount of generated power Q_{electric} of the solar panel, is divided by 2.1 W, 91.4 is obtained, and thus it is possible to simultaneously supply power to 91 fuel cells to be operated.

One reversible fuel cell generates, for example, 420 ml/h of hydrogen and 210 ml/h of oxygen. Therefore, in the case of 10 fuel cells, 100,800 (=420 (ml/h)×24 (h)×10) ml, that is, 100.8 L of hydrogen can be generated and 50,400 (=210 (ml/h)×24 (h)×10) ml, that is, 50.4 L of oxygen can be generated during the initial daytime period of 10 days.

### (3) Operable Period in Low Power Mode Using Fuel Cell as Power Source

For example, assuming that an output voltage at the time of generating power through water synthesis of the fuel cell is, for example, 0.6 V and an output current is 360 mA, output power is 0.21 (=0.6×0.36) W. When 1.365 W is designated as the power consumption in the low power mode by the user as illustrated in FIG. 5, 1.365 W/0.21 W is 6.5, and thus, 7 or more fuel cells are required to output the power consumption in the low power mode. The display 17 of the terminal 1 may display that seven or more fuel cells are mounted as a configuration of the rover, or that seven or more fuel cells are required as a configuration of the rover.

In order to realize this display, the processor 26 may output information for presenting that seven or more fuel cells are mounted as a configuration of the rover or information for presenting the number of fuel cells required as a configuration of the rover by executing the above calculation.

In the following description, it is assumed that the rover 3 has seven fuel cells. Assuming that a hydrogen amount per unit time consumed at the time of power generation in the fuel cell is x (ml/h) and an oxygen amount per unit time is y (ml/h), and a hydrogen storage amount in the hydrogen tank 36 and an oxygen storage amount in the oxygen tank 37 are X and Y, respectively, an operable period Z in the low power mode using the fuel cell as a power source is expressed by the following equation.

$$Z = min ( X / x , Y / y )$$

The processor 26 may output the operable period Z in the low power mode as an extension period of the mission by calculating the above equation.

As described above, in a case where the mission period is input by the user in addition to the target point on the heavenly body (for example, the Moon) other than the Earth, the processor 26 may calculate an amount of power generated by the solar panel of the rover at the target point on the basis of the schedule, and output an amount of hydrogen/oxygen generated by the fuel cell in the daytime of the mission period by using the amount of power on the heavenly body (for example, the Moon) other than the Earth.

The processor 26 may output the extension period of the mission or the total period of the mission in a case where the rover is operated in the low power mode at night of the heavenly body (for example, the Moon) other than the Earth by using a reserved amount of hydrogen and a reserved amount of oxygen obtained from the amount of hydrogen/oxygen generated in the fuel cell in the daytime of the heavenly body other than the Earth.

### <Searching for Landing Candidate Points>

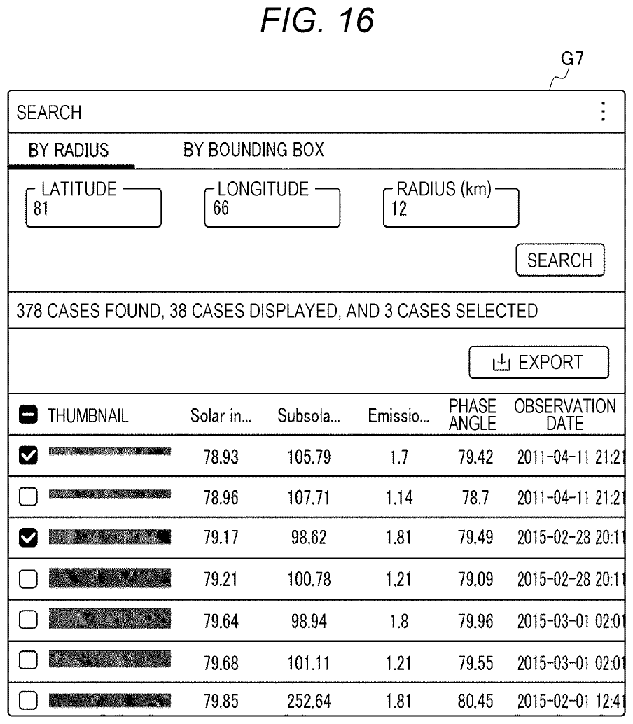

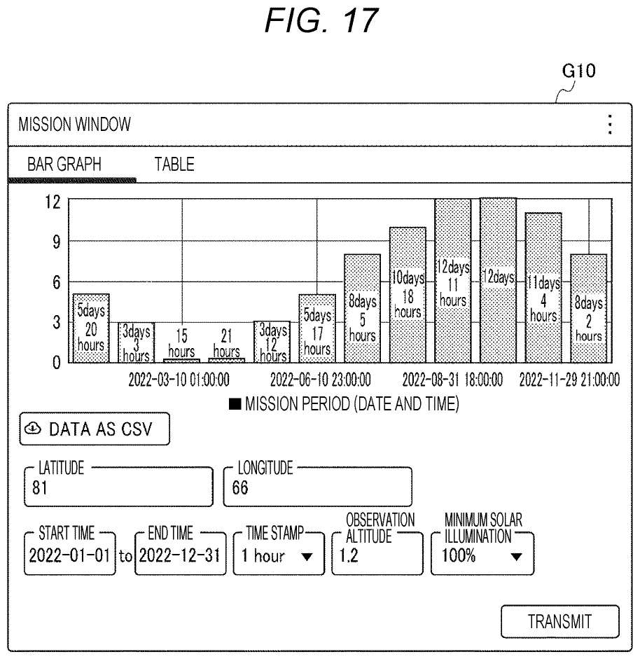

Next, searching for landing candidate points will be described with reference to FIG. 16. FIG. 16 illustrates an example of a landing candidate point search screen. A latitude and a longitude, and a radius of a circle centered on a point of the latitude and the longitude for specifying a search range are displayed to be input by the user on a screen G7. Here, when a “search” button is pressed, searching is executed. On the lower half of the screen G7, candidate points that are centered on the point of the designated latitude and longitude and are within a circle of the designated radius are displayed in a list.

In order to realize this processing, the storage device 23 may store a latitude, a longitude, and an altitude on the Moon surface in association with each other. In this case, in a case where the processor 26 receives the latitude, the longitude, and the search range centered on the point of the latitude and the longitude from the user, the processor may search the storage device 23 and output a point where the obliquity falls within a predetermined range as a landing candidate point. As a result, a flat point that satisfies a criterion is output. As described above, in a case where a condition desired by the user is received, a point on a heavenly body other than the Earth that satisfies the condition is searched for, and the search result is output.

### <Mission Continuation Period>

Next, a mission continuation period will be described. Since the Moon changes day and night every 14 days, a mission continuation period varies depending on the start date and time of the mission. The mission continuation period is displayed for each start date and time of the mission so that the mission continuation period can be easily ascertained.

FIG. 17 illustrates an example of a bar graph illustrating the mission continuation period for each mission start date and time. A latitude, a longitude, the start date and the end date of a period, and an altitude on the Moon surface are displayed to be able to be input on a screen G10 in FIG. 17. When a “transmit” button is pressed on the screen G9 in FIG. 17, a bar graph is displayed on the screen G9 in FIG. 17. The vertical axis represents the mission continuation period, and the horizontal axis represents the date. Here, as an example, since Jan. 1, 2022 to Dec. 31, 2022 is input as the period, respective mission continuation periods when the mission is started on the first day of each month in 2022 are indicated by bar graphs. As described above, the mission continuation period varies depending on the date of starting the mission.

In order to realize this display, the storage device 23 stores information regarding a day period of the Moon surface and/or a night period of the Moon surface in unit time intervals (for example, 1 hour). In this case, the processor 26 refers to the storage device 23, acquires a daytime or a nighttime for each mission start date at unit time (for example, 1 hour) after the mission start date, calculates an amount of power generated from the solar panel and amounts of oxygen and hydrogen generated by the fuel cell on the basis of the amount of generated power in the daytime, and calculates a duration for which the fuel cell will be able to generate power from oxygen and hydrogen in the fuel cell in the nighttime, thereby outputting the mission continuation period for each mission start date.

### <Display of Mission Continuation Period at Each Point>

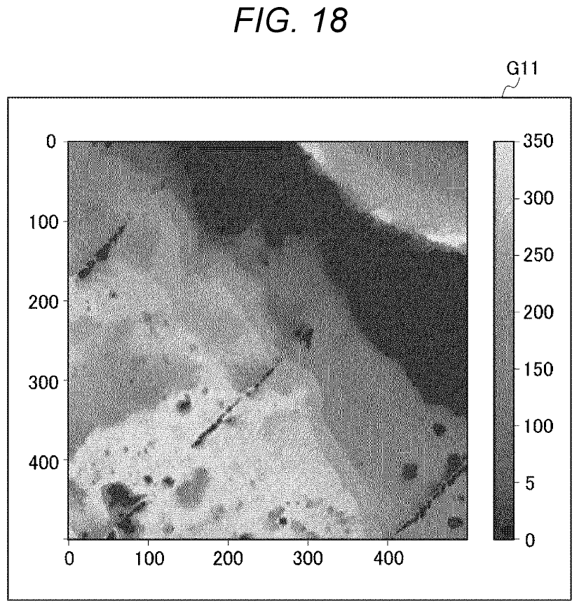

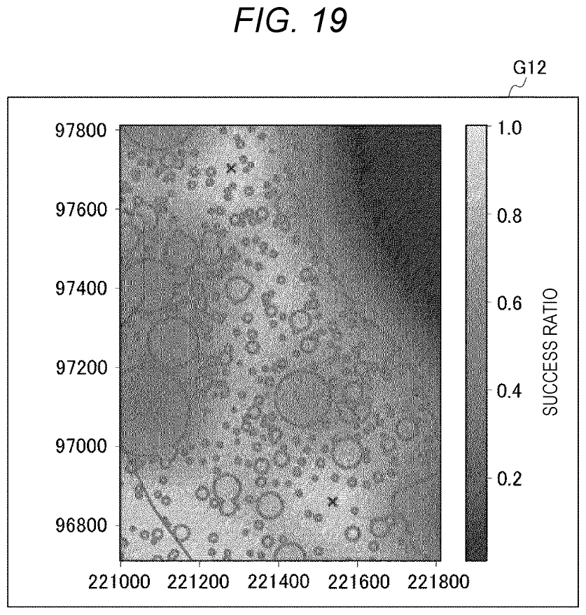

Display of the mission continuation period at each point will be described with reference to FIG. 18. FIG. 18 illustrates an example of a screen that includes a graph representing a mission continuation period for each point on the Moon surface by color. The horizontal axis and the vertical axis of the graph on a screen G11 in FIG. 18 represent distances. In the graph on the screen G11 in FIG. 18, mission continuation periods at respective points of 500 km square centered on the latitude and the longitude designated by the user are indicated by colors. The mission continuation period is a period corresponding to a case where the user has designated the mission start date.

In order to realize this display, the storage device 23 stores information regarding the day period of the Moon surface and/or the night period of the Moon surface in unit time intervals (for example, 1 hour). In this case, for example, when receiving the latitude, the longitude, and the mission start date, the processor 26 refers to the storage device 23 to acquire a daytime or a nighttime for each unit time (for example, 1 hour) after the mission start date for each point in a predetermined range (for example, 500 km square) centered on the latitude and the longitude designated by the user, calculates an amount of power generated from the solar panel and amounts of oxygen and hydrogen generated by the fuel cell on the basis of the amount of generated power in the daytime, and calculates a duration for which the fuel cell will be able to generate power from oxygen and hydrogen in the fuel cell in the nighttime, thereby outputting the mission continuation period for each point. The processor 26 outputs, for example, information for displaying the mission continuation period at each point in a graph.

### <Landing Success Probability at Each Point>

Display of a landing success probability at each point will be described with reference to FIG. 19. FIG. 19 illustrates an example of a screen including a graph representing a landing success probability at each point on the Moon surface by color. The horizontal axis and the vertical axis of the graph on a screen G12 in FIG. 19 represent distances. In the graph on the screen G12 in FIG. 19, a landing success probability at each point in a predetermined range centered on a latitude and a longitude designated by the user is indicated by color. In the graph on the screen G12 in FIG. 19, the landing candidate points are indicated by cross marks.

In order to realize this display, a latitude, a longitude, and an altitude on the Moon are stored in association with each other in the storage device 23. In this case, for example, in a case where the processor 26 receives a latitude and a longitude serving as a landing candidate in the Moon, the processor refers to the storage device 23 and calculates the landing success probability for each point in a predetermined range centered on the latitude and the longitude designated by the user according to a predetermined calculation formula, thereby outputting a landing success probability for each point. In addition, for example, in a case where the processor 26 receives a latitude and a longitude serving as a landing candidate in the Moon, the processor may specify a position of a crater and a range thereof with reference to the storage device 23. In addition, for example, in a case where the processor 26 receives a latitude and a longitude serving as a landing candidate in the Moon, the processor may refer to the storage device 23 to select and output at least one landing candidate point in accordance with a predetermined selection rule (for example, a point having the highest success probability) from among points where the landing success probability exceeds a predetermined threshold and where the position of the crater is excluded.

As described above, the information processing system according to the present embodiment includes at least one processor that executes calculation according to an operation of a user by using at least one of water resource data corresponding to each of points on a heavenly body other than the Earth, environmental data corresponding to each of points on the heavenly body other than the Earth, a specification and/or a given setting value of a rover, a specification and/or a given setting value of a device, an input value of the user, and a given setting value, to output information regarding a mission on the heavenly body other than the Earth.

As a result, since the user can ascertain information regarding a mission in advance, it is possible to efficiently plan a mission.

In addition, at least a part of the computer system 2 described in the above-described embodiment may be configured by hardware or software. In a case where the computer system 2 is configured by software, a program for realizing at least some functions of the computer system 2 may be stored in a computer-readable recording medium and read and executed by a computer. The recording medium is not limited to a removable recording medium such as a magnetic disk or an optical disc, and may be a stationary recording medium such as a hard disk device or a memory.

In addition, a program for realizing at least some functions of the computer system 2 may be distributed via a communication line (including wireless communication) such as the Internet. Further, the program may be distributed via a wired line or a wireless line such as the Internet or by being stored in a recording medium in an encrypted, modulated, or compressed state.

Furthermore, the computer system 2 may be caused to function by one or a plurality of information apparatuses. In the case of using a plurality of information apparatuses, one of the information apparatuses may be a computer, and the computer may execute a predetermined program to realize a function as at least one means of the computer system 2.

Further, in the invention of the method, all the processes (steps) may be realized by automatic control using a computer. In addition, while causing a computer to perform each process, progress control between processes may be performed manually. Furthermore, at least some of all steps may be performed manually.

As described above, the present invention is not limited to the above-described embodiment as it is, and can be embodied by modifying the components without departing from the gist of the present invention in the implementation stage. In addition, various inventions can be formed by appropriately combining a plurality of components disclosed in the above embodiment. For example, some components may be deleted from all the components shown in the embodiments. Furthermore, components in different embodiments may be appropriately combined.

### REFERENCE SIGN LIST

1 Terminal
11 Input interface
12 Communication module
13 Storage device
14 Memory
15 Output interface
16 Processor
17 Display
2 Computer system
21 Input interface
22 Communication module
23 Storage device
24 Memory
25 Output interface
26 Processor
3 Rover
31 Housing
32-1, 32-2 Wheel
33 Solar panel
34 Fuel cell
35 Water tank
36 Hydrogen tank
37 Oxygen tank
38 Processor
39 Motor

1. An information processing system comprising: at least one processor configured to output information regarding a mission to a heavenly body other than the Earth by executing processing according to an operation of a user by using at least one of water resource data corresponding to each of points on the heavenly body other than the Earth, environmental data corresponding to each of points on the heavenly body other than the Earth, a specification and/or a given setting value of a rover, a specification and/or a given setting value of a device, an input value of the user, and a given setting value.

2. The information processing system according to claim 1, wherein
the output information regarding the mission is information regarding at least one of an exploration route and/or a consumed energy of the rover, an amount of water extracted by a water decomposer, an amount of power generated by a fuel cell, and an amount of hydrogen or oxygen generated by the fuel cell.

3. The information processing system according to claim 1, further comprising:
at least one storage device that stores water resource data including water reserves and/or a predicted water content of a regolith for each of positions on the heavenly body other than the Earth, wherein
the at least one processor updates water resource data corresponding to each of points on the heavenly body other than the Earth in accordance with remote sensing of a sensor provided in a satellite that orbits the heavenly body other than the Earth and/or a detection result from a sensor provided on a surface of or underground in the heavenly body other than the Earth.

4. The information processing system according to claim 3, wherein
the at least one processor simulates a mission on the heavenly body other than the Earth by using the updated water resource data, and outputs information regarding a simulation result.

5. The information processing system according to claim 1, wherein
the information regarding the mission is an acquisition cost of a water resource at a point designated by the user, and
the at least one processor outputs the acquisition cost of the water resource at the point designated by the user by using environmental data corresponding to each of points on the heavenly body other than the Earth.

6. The information processing system according to claim 1, wherein
the device is a water decomposer,
the information regarding the mission is information regarding water extraction, and
the at least one processor outputs the information regarding water extraction by executing processing according to an operation of the user by using a specification of the water decomposer and/or a given setting value in addition to the water resource data.

7. The information processing system according to claim 6, wherein
the information regarding water extraction is an amount of water generated per unit time and/or a time required to acquire a target amount of water,
the water resource data is a predicted water content of a regolith, and
the at least one processor outputs the amount of water generated per unit time and/or the time required to acquire the target amount of water by using an efficiency of the water decomposer extracting water from the regolith, a regolith weight that is treatable per unit time in the water decomposer, and a predicted water content of the regolith.

8. The information processing system according to claim 1, wherein,
in a case where a start point on the heavenly body other than the Earth and at least one target point on the heavenly body other than the Earth are input, the at least one processor outputs at least one of a first candidate route from the start point to the target point, a distance of the first candidate route, and a maximum obliquity in the first candidate route.

9. The information processing system according to claim 8, wherein
the at least one processor outputs a difference in maximum obliquity and/or a difference in distance between the first candidate route and one or more second candidate routes different from the first candidate route.

10. The information processing system according to claim 9, wherein
the at least one processor outputs a recommended specification of a rover corresponding to the second candidate route.

11. The information processing system according to claim 8, further comprising
at least one storage device that stores a relationship between a ratio between a horizontal traction force and a vertical load and a slip ratio for each speed of the rover, wherein,
in a case where a set speed of the rover is received from the user, the at least one processor obtains a ratio between a horizontal traction force and a vertical load at each movement point of the rover, determines a slip ratio corresponding to the obtained ratio in the relationship stored in the storage device, and outputs an arrival prediction time at or a required time to reach the target point by using the slip ratio.

12. The information processing system according to claim 8, further comprising
at least one storage device that stores a relationship between a ratio between a horizontal traction force and a vertical load and a slip ratio for at least a minimum set speed of the rover, wherein
the at least one processor updates the relationship between the ratio between the horizontal traction force and the vertical load and the slip ratio in the storage device by using information acquired from the heavenly body other than the Earth, and outputs a maximum climbing possible inclination angle of the rover with reference to the updated relationship.

13. The information processing system according to claim 1, wherein
the device is one or more fuel cells, and
in a case where the user inputs a mission period in addition to a target point on the heavenly body other than the Earth, the at least one processor calculates an amount of power generated by a solar panel of the rover at the target point on the basis of the mission period, and outputs an amount of hydrogen/oxygen generated by the fuel cells in the daytime of the mission period in the heavenly body other than the Earth by using the amount of power.

14. The information processing system according to claim 13, wherein
the at least one processor outputs an extension period of the mission or a total period of the mission in a case where the rover is operated in a low power mode at night of the heavenly body other than the Earth by using a reserved amount of hydrogen and a reserved amount of oxygen obtained from the amount of hydrogen/oxygen generated by the fuel cells in the daytime of the heavenly body other than the Earth.

15. The information processing system according to claim 1, further comprising
a storage device that stores a latitude, a longitude, and an altitude on a Moon surface in association with each other, wherein
in a case where the at least one processor receives the latitude, the longitude, and a search range centered on a point of the latitude and the longitude from the user, the at least one processor searches the storage device, and outputs a point where an obliquity falls within a predetermined range as a landing candidate point.

16. The information processing system according to claim 1, wherein,
in a case where a point and a time period for the heavenly body other than the Earth are received from the user, the at least one processor outputs a mission continuation period in a time period division obtained by dividing the received period.

17. The information processing system according to claim 1, further comprising
a storage device that stores information regarding a daytime period of the heavenly body other than the Earth and/or a nighttime period of the heavenly body other than the Earth in unit time intervals, wherein
the at least one processor refers to the storage device to acquire, for each mission start date, a daytime or a nighttime for each unit time after the mission start date, calculates an amount of power generated from a solar panel and amounts of oxygen and hydrogen generated by a fuel cell by using the amount of generated power in the daytime, and calculates a duration for which the fuel cell will be able to generate power from oxygen and hydrogen in the fuel cell in the nighttime, thereby outputting a mission continuation period for each mission start date.

18. The information processing system according to claim 1, further comprising
a storage device that stores information regarding a daytime period of the heavenly body other than the Earth and/or a nighttime period of the heavenly body other than the Earth in unit time intervals, wherein
in a case where a latitude, a longitude, and a mission start date are received, the at least one processor refers to the storage device to acquire a daytime or a nighttime for each unit time after the mission start date for each point in a predetermined range centered on the latitude and the longitude designated by the user, calculates an amount of power generated from a solar panel and amounts of oxygen and hydrogen generated by a fuel cell by using the amount of generated power in the daytime, and calculates a duration for which the fuel cell will be able to generate power from oxygen and hydrogen in the fuel cell in the nighttime, thereby outputting a mission continuation period for each point.

19. The information processing system according to claim 1, further comprising
a storage device that stores a latitude, a longitude, and an altitude on the heavenly body other than the Earth in association with each other, wherein
in a case where a latitude and a longitude serving as a landing candidate on the heavenly body other than the Earth are received, the at least one processor refers to the storage device and calculates a landing success probability for each point in a predetermined range centered on the latitude and the longitude designated by the user according to a predetermined calculation formula, thereby outputting a landing success probability for each point.

20. An information processing method comprising a step of outputting information regarding a mission on a heavenly body other than the Earth by executing processing according to an operation of a user by using at least one of water resource data corresponding to each of points on the heavenly body other than the Earth, environmental data corresponding to each of points on the heavenly body other than the Earth, a specification and/or a given setting value of a rover, a specification and/or a given setting value of a device, an input value of the user, and a given setting value.

21. A computer-readable recording medium storing a program for causing a computer to execute a step of outputting information regarding a mission on a heavenly body other than the Earth by executing processing according to an operation of a user by using at least one of water resource data corresponding to each of points on the heavenly body other than the Earth, environmental data corresponding to each of points on the heavenly body other than the Earth, a specification and/or a given setting value of a rover, a specification and/or a given setting value of a device, an input value of the user, and a given setting value.
